(19) United States
(12) Patent Application Publication
(10) Pub. No.: US 2026/0149393 A1
(43) Pub. Date: May 28, 2026

(54) ELECTROSTATIC CHUCK ASSEMBLY AND DEPOSITION APPARATUS INCLUDING THE SAME

(71) Applicant: Samsung Display Co., Ltd., Yongin-si (KR)

(72) Inventors: MYUNGKYU KIM, Yongin-si (KR); HYEONSIK KIM, Yongin-si (KR); YONG YEO, Yongin-si (KR); YONGSIC JEON, Yongin-si (KR); KYUNGHOON CHUNG, Yongin-si (KR)

(21) Appl. No.: 19/243,183

(22) Filed: Jun. 19, 2025

(30) Foreign Application Priority Data
Nov. 26, 2024 (KR) 10-2024-0171118

(51) Int. Cl. H02N 13/00; B23Q 3/154

(52) U.S. Cl. CPC H02N 13/00; B23Q 3/1543; B23Q 3/1546

(57) ABSTRACT

An electrostatic chuck assembly includes an electrostatic chuck, a reinforcement frame, and actuators. The electrostatic chuck has a first surface configured to attach a substrate and a second surface opposite to the first surface. The reinforcement frame has an upper surface portion spaced apart from and facing the second surface of the electrostatic chuck and a connecting portion connecting the upper surface portion with the electrostatic chuck. The actuators are coupled to the electrostatic chuck and the upper surface portion and are configured to generate a pushing or pulling force on the electrostatic chuck in a third direction intersecting a first direction and a second direction parallel to the second surface of the electrostatic chuck according to an electrical supply.

### CROSS-REFERENCE TO RELATED APPLICATION

The present application claims priority to and the benefit of Korean Patent Application No. 10-2024-0171118, filed on Nov. 26, 2024, in the Korean Intellectual Property Office, the entire disclosure of which is incorporated herein by reference.

### BACKGROUND

### 1. Field

Aspects of embodiments of the present disclosure relates to an electrostatic chuck assembly and a deposition apparatus including the same.

### 2. Description of the Related Art

Electronic devices, such as smartphones, digital cameras, notebook computers, navigation systems, and smart televisions, that provide images to users include display devices. A display device generates an image and provides the generated image to the user through a display screen. Various display panels, such as liquid crystal display (LCD) panels and organic light-emitting diode (OLED) display panels, have been developed for use in display devices.

From among these display panels, an OLED display panel includes self-emissive light-emitting diodes. Each light-emitting diode includes an anode, a cathode, and an emissive layer. The emissive layer includes an organic material. A deposition process can be used to form the emissive layer on the display panel.

The deposition process may involve positioning a mask between a substrate of the display panel and a deposition source, with the organic material supplied from the deposition source and deposited onto the substrate through the mask. If the substrate or the mask sags, a shadow region may be formed between the substrate and the mask, causing deposition defects where the organic material is misaligned from the target position. An electrostatic chuck is a device that reduces or minimizes the sagging of the substrate by using electrostatic force.

### SUMMARY

Embodiments of the present disclosure provide an electrostatic chuck assembly that automatically controls the flatness of an electrostatic chuck and a deposition apparatus including the same.

In one embodiment of the present disclosure, an electrostatic chuck assembly includes an electrostatic chuck, a reinforcement frame, and actuators. The electrostatic chuck has a first surface configured to attach a substrate and a second surface opposite to the first surface. The reinforcement frame has an upper surface portion, which is spaced apart from and facing the second surface of the electrostatic chuck, and a connecting portion that connects the upper surface portion with the electrostatic chuck. The actuators are coupled to the electrostatic chuck and the upper surface portion and configured to generate a pushing or pulling force in a third direction intersecting a first direction and a second direction parallel to the second surface of the electrostatic chuck, according to an electrical supply.

According to one embodiment of the present disclosure, the connecting portion may be coupled to opposite ends of the electrostatic chuck in the first direction or the second direction.

According to one embodiment of the present disclosure, the upper surface portion may have a third surface facing the electrostatic chuck and a fourth surface opposite to the third surface. The connecting portion may be detachably coupled to the upper surface portion through fasteners, which are coupled to the connecting portion by penetrating the fourth surface and the third surface of the upper surface portion.

According to one embodiment of the present disclosure, the electrical supply to each of the actuators may be independently controlled.

According to one embodiment of the present disclosure, each of the actuators may include a piezo actuator having an adjustable length depending on the electrical supply.

According to one embodiment of the present disclosure, the actuators may include first actuators and second actuators. The first actuators may be arranged in a ring shape along a peripheral region of the second surface of the electrostatic chuck, and the second actuators may be arranged in a central region of the second surface defined by the peripheral region.

According to one embodiment of the present disclosure, the actuators may be arranged in a matrix having at least three rows and three columns.

According to one embodiment of the present disclosure, the second surface may have a first side extending in the first direction and a second side extending in the second direction intersecting the first direction. Each of the second actuators may be arranged between a pair of first actuators from among the first actuators along the first direction and between another pair of first actuators from among the first actuators along the second direction.

According to one embodiment of the present disclosure, the actuators may be detachably coupled to the electrostatic chuck via permanent electromagnets and magnetic members. The permanent electromagnets may be coupled to ends of the actuators, and the magnetic members may be coupled to the electrostatic chuck and detachably coupled to the permanent electromagnets by a magnetic force provided by each of the permanent electromagnets.

According to one embodiment of the present disclosure, each of the permanent electromagnets may be switched to a magnetic-on state or a magnetic-off state each time electricity is supplied, and the magnetic-on or magnetic-off state may remain after the electricity supply is interrupted.

According to one embodiment of the present disclosure, the electrostatic chuck assembly may further include first magnetic shielding caps and second magnetic shielding caps. The first magnetic shielding caps may extend around each of the permanent electromagnets while exposing a first attachment surface. The second magnetic shielding caps may extend around each of the magnetic members while exposing a second attachment surface. The first attachment surface of each of the permanent electromagnets and the second attachment surface of each of the magnetic members may face each other to be adhered to each other by magnetic force.

According to one embodiment of the present disclosure, the electrostatic chuck assembly may further include a magnet plate. The magnet plate may be configured to move vertically between the electrostatic chuck and the upper surface portion. The magnet plate may include a plate portion and magnets. The plate portion may have a fifth surface facing the electrostatic chuck and a sixth surface opposite to the fifth surface. The magnets may each be coupled to the fifth surface of the plate portion.

According to one embodiment of the present disclosure, the plate portion may have through-holes accommodating the actuators, and the through-holes may be arranged not to overlap with the magnets in a plan view.

An electrostatic chuck assembly, according to another embodiment of the present disclosure, may include an electrostatic chuck, a reinforcement frame, and flatness control structures. The electrostatic chuck has a first surface to which a substrate is attached and a second surface opposite to the first surface. The reinforcement frame has an upper surface portion, which is spaced apart from and facing the second surface of the electrostatic chuck, and a connecting portion that connects the upper surface portion with the electrostatic chuck. The flatness control structures are coupled to the electrostatic chuck and the upper surface portion and are configured to generate a pushing or pulling force in a third direction perpendicular to the second surface of the electrostatic chuck. The flatness control structures are detachably coupled to the electrostatic chuck via permanent electromagnets and magnetic members. The permanent electromagnets are coupled, respectively, to ends of the flatness control structures. The magnetic members are each be coupled to the electrostatic chuck and are detachably coupled to the permanent electromagnets by magnetic force provided by each of the permanent electromagnets.

According to one embodiment of the present disclosure, the upper surface portion may have a third surface facing the electrostatic chuck and a fourth surface opposite to the third surface. The connecting portion may be detachably coupled to the upper surface portion by fasteners, which are coupled to the connecting portion by extending through the fourth surface and the third surface of the upper surface portion.

According to one embodiment of the present disclosure, the electrostatic chuck assembly may further include first magnetic shielding caps and second magnetic shielding caps. The first magnetic shielding caps may extend around each of the permanent electromagnets while exposing a first attachment surface. The second magnetic shielding caps may extend around each of the magnetic members while exposing a second attachment surface. The first attachment surface of each of the permanent electromagnets and the second attachment surface of each of the magnetic members may face each other to be adhered to each other by magnetic force.

A deposition apparatus, according to another embodiment of the present disclosure, may include a vacuum chamber, a deposition source, an electrostatic chuck assembly, and mask holders. The deposition source is arranged in the vacuum chamber and is configured to supply deposition material into the vacuum chamber. The electrostatic chuck assembly is above the deposition source and has a substrate attached thereto. The mask holders support both ends of a mask between the deposition source and the substrate. The electrostatic chuck assembly includes an electrostatic chuck, a reinforcement frame, and actuators. The electrostatic chuck has a first surface to which the substrate is attached and a second surface opposite to the first surface. The reinforcement frame has an upper surface portion spaced apart from and facing the second surface of the electrostatic chuck and a connecting portion that connects the upper surface portion with the electrostatic chuck. The actuators are coupled to the electrostatic chuck and the upper surface portion and configured to generate a pushing or pulling force in a third direction, which intersects a first direction and a second direction parallel to the second surface of the electrostatic chuck, according to an electrical supply.

According to one embodiment of the present disclosure, the electrostatic chuck may overlap at least a portion of each of a pair of the mask holders in a plan view.

According to one embodiment of the present disclosure, the deposition apparatus may further include sensors and a controller. The sensors may be configured to measure a distance between the electrostatic chuck and the upper surface portion in the third direction corresponding to each of the actuators. The controller may be configured to automatically adjust the flatness of the electrostatic chuck by individually controlling the electrical supply to each of the actuators based on measurements from the sensors.

According to one embodiment of the present disclosure, the actuators may include first actuators and second actuators. The first actuators may be arranged in a ring shape along a peripheral region of the second surface of the electrostatic chuck, and the second actuators may be arranged in a central region of the second surface defined by the peripheral region. An elevation distance of second regions of the electrostatic chuck by the second actuators may be greater than an elevation distance of first regions of the electrostatic chuck by the first actuators.

According to embodiments of the present disclosure, the flatness of the electrostatic chuck may be automatically adjusted by individually controlling the electrical supply to each of the actuators.

In addition, difficulties in performing flatness adjustment operations in the central region of a large-area electrostatic chuck due to a confined working space may be mitigated or avoided.

### BRIEF DESCRIPTION OF THE DRAWINGS

These and/or other aspects and features of the present disclosure will become apparent and more readily appreciated from the following description of embodiments, taken in conjunction with the accompanying drawings, in which:

FIG. 1 is a diagram illustrating an electrostatic chuck assembly according to an embodiment of the present disclosure;

FIG. 2 is a plan view of the electrostatic chuck assembly shown in FIG. 1;

FIG. 3 is an enlarged view of the area A in FIG. 2;

FIG. 4 is a plan view of the electrostatic chuck shown in FIG. 1;

FIG. 5 is a bottom view of a portion of the magnet plate shown in FIG. 1;

FIG. 6 is a cross-sectional view taken along the line I-I in FIG. 2;

FIG. 7 is a diagram illustrating the permanent electromagnet and the magnetic member shown in FIG. 6 in a separated state;

FIGS. 8 and 9 illustrate an electrostatic chuck assembly according to another embodiment of the present disclosure;

FIG. 10 is a diagram illustrating a deposition apparatus according to an embodiment of the present disclosure;

FIG. 11 is a schematic diagram illustrating a controller of the deposition apparatus shown in FIG. 10;

FIGS. 12 and 13 are diagrams comparing the flatness of the electrostatic chuck before and after automatic flatness adjustment in the deposition apparatus shown in FIG. 10;

FIGS. 14 to 16 are diagrams illustrating a method of attaching and detaching the electrostatic chuck shown in FIG. 10; and

FIG. 17 is a cross-sectional view illustrating a display panel manufactured by using the deposition apparatus according to an embodiment of the present disclosure.

### DETAILED DESCRIPTION

References will now be made, in detail, to embodiments, examples of which are illustrated in the accompanying drawings. The embodiments may have a variety of forms and permutations, and the present disclosure shall by no means be construed as being limited to the embodiments described herein. Rather, the present disclosure shall be construed to encompass all forms, permutations, equivalents, and substitutes covered by the technical ideas and scope of the present disclosure. Accordingly, some embodiments are merely described below, by referring to the figures, to explain aspects and features of the present disclosure.

Like or identical reference numerals refer to like or identical elements. Moreover, in the accompanying drawings, the thicknesses, ratios, and dimensions of the elements may not be to exact scale and may be exaggerated for the benefit of effective explanation of the technical features associated with these elements. As such, the present disclosure shall not be restricted to the thicknesses, ratios, dimensions, etc. illustrated in the drawings.

When an element is described as being “disposed on,” “placed on,” “arranged on,” “connected to,” or “coupled to” another element, it shall be construed as being disposed on, placed on, arranged on, connected to, or coupled to the other element directly but also as possibly having another element therebetween. On the other hand, if one element is described as being “directly disposed on,” “directly placed on,” “directly arranged on,” “directly connected to,” or “directly coupled to” another element, it shall be understood that there is no other element interposed therebetween.

Moreover, relative terms, such as “below,” “under,” “beneath,” “lower,” “bottom,” “above,” “over,” “upper,” “top,” etc., may be used herein to describe one element's relationship to another element as illustrated in the accompanying figures. It shall be understood that relative terms are intended to encompass different orientations of the device in addition to the orientation depicted in the accompanying figures. For example, if the device in one of the figures is turned over, elements described as being on the “lower” side of the other elements would then be oriented on “upper” sides of the other elements. Thus, the exemplary term “lower” can therefore encompass an orientation of both “lower” and “upper,” depending on the particular orientation of the figure. Similarly, if the device in one of the figures is turned over, elements described as “below” or “beneath” other elements would then be oriented “above” the other elements. Thus, the exemplary terms “below” or “beneath” can therefore encompass an orientation of both above and below.

Furthermore, when one device or layer is described to be “on,” “over,” “above,” and the like, another device or layer, it shall also encompass the case of yet another device or layer disposed on, over, above, and the like, the other device or layer or interposed between the one device or layer and the other device or layer. On the contrary, when one device or layer is described to be “directly on,” “directly over,” “directly above,” and the like, another device or layer, it shall mean that no other device or layer is interposed between the one device or layer and the other device or layer.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

Terms such as “first” and “second” may be used in describing various elements, but the above elements shall not be restricted to the above terms. The above terms may be used only to distinguish one element from the other. For instance, the first element may be named the second element, and vice versa, without departing the scope of claims of the present disclosure. Unless clearly used otherwise, any expressions in a singular form may include a meaning of a plural form. The term “and/or” shall include the combination of a plurality of listed items or any of the plurality of listed items.

As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

In embodiments of the present disclosure, directions labeled as first through third directions DR1-DR3 may be referred to. The first direction DR1 may be parallel to a first side of a second surface of an electrostatic chuck ESC. The second direction DR2 may cross (or may intersect) the first direction DR1 and may be parallel to a second side of the second surface of the electrostatic chuck ESC. The third direction DR3 may be perpendicular to the second surface of the electrostatic chuck ESC. In embodiments of the present disclosure, the phrase “in a plan view” refers to a view taken along the third direction DR3.

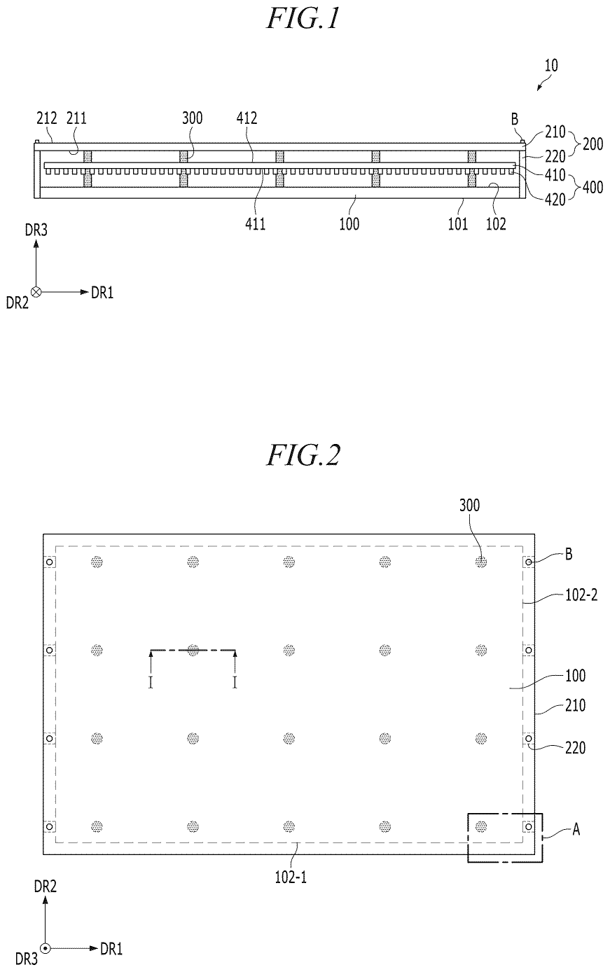

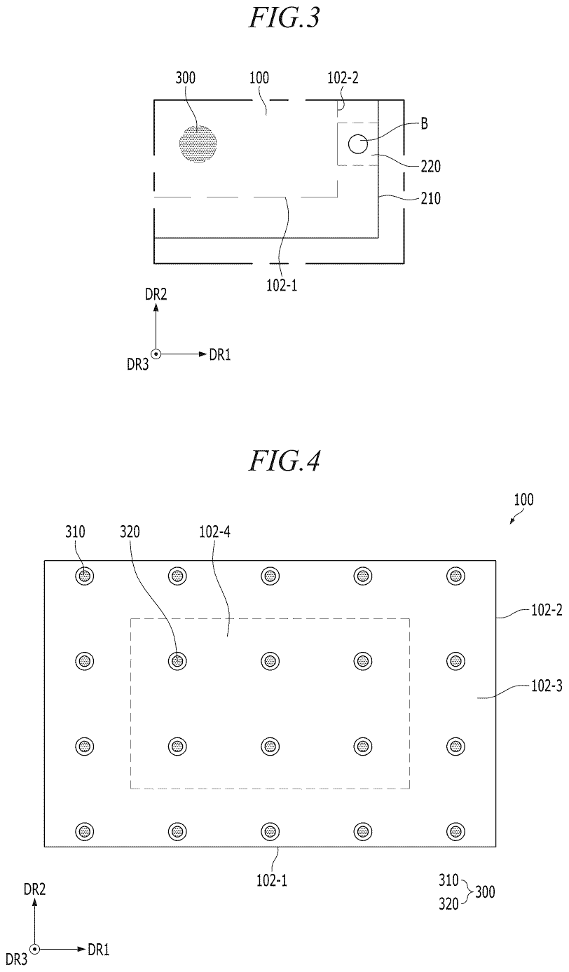

FIG. 1 illustrates an electrostatic chuck assembly according to an embodiment of the present disclosure, FIG. 2 is a plan view of the electrostatic chuck assembly shown in FIG. 1, and FIG. 3 is an enlarged view of the area A in FIG. 2. Referring to FIGS. 1 to 3, an electrostatic chuck assembly 10, according to an embodiment of the present disclosure, may include an electrostatic chuck 100, a reinforcement frame 200, actuators 300, and a magnet plate 400. However, the electrostatic chuck assembly 10 is not limited to including all of the above-listed components, and in various embodiments, one or more of these components may be omitted. In FIGS. 2 and 3, for ease of understanding, the electrostatic chuck 100, a connecting portion 220 of the reinforcement frame 200, and the actuators 300, which are hidden under an upper surface portion 210 of the reinforcement frame 200 in the plan view, are indicated with dashed lines.

The electrostatic chuck 100 is a device configured to chuck or de-chuck (e.g., to attach or detach) a substrate by using electrostatic force. The electrostatic chuck 100 may have a first surface 101 and a second surface 102. The substrate may be attached to the first surface 101 by electrostatic force. The second surface 102 may be an opposite surface of the first surface 101 and may have a first side (e.g., a first edge) 102-1 and a second side (e.g., a second edge) 102-2. The first side 102-1 may extend in the first direction DR1, and the second side 102-2 may extend in the second direction DR2, which crosses (or intersects) the first direction DR1. The first side 102-1 may be the long side of the electrostatic chuck 100, and the second side 102-2 may be the short side. For example, the second surface 102 may have a rectangular shape in which the first side 102-1 is longer than the second side 102-2, but it is not limited to this configuration.

The electrostatic chuck 100 may be a large-area chuck, such that the lengths of the first side 102-1 and the second side 102-2 may be several meters, while the thickness of the electrostatic chuck 100 may be only a few tens of millimeters. As the electrostatic chuck 100 becomes larger, issues related to stiffness and sagging of the electrostatic chuck 100 may arise.

The reinforcement frame 200 may act as a reinforcing structure to supplement (or increase) the stiffness of the electrostatic chuck 100. The reinforcement frame 200 may have an upper surface portion 210 and a connecting portion 220. The upper surface portion 210 may be spaced apart from and arranged to face the second surface 102 of the electrostatic chuck 100 in the third direction DR3. As a result, between the upper surface portion 210 and the electrostatic chuck 100 may be a space in which the actuators 300 and the magnet plate 400 are arranged.

The upper surface portion 210 may have a third surface 211, which may face the second surface 102 of the electrostatic chuck 100, and a fourth surface 212, which may be opposite to the third surface 211. The upper surface portion 210 may be formed as an integral plate, as illustrated, but it is not limited to this configuration and may also have a divided structure.

The connecting portion 220 may connect the upper surface portion 210 with the electrostatic chuck 100. Referring to FIG. 1, the connecting portion 220 may be coupled to both ends (e.g., opposite ends) of the electrostatic chuck 100 in the first direction DR1. The connecting portion 220 is illustrated as being coupled at four locations along each end in the first direction DR1, but this is merely an example and not a limitation. In another embodiment, the connecting portion 220 may be coupled to both ends (e.g., opposite ends) of the electrostatic chuck 100 in the second direction DR2. In yet another embodiment, the connecting portion 220 may be coupled to both ends (e.g., opposite ends) in the first direction DR1 and the second direction DR2. The connecting portion 220 may be non-overlapping with (e.g., may not overlap or may be offset from) the electrostatic chuck 100 in a plan view.

The connecting portion 220 may be detachably coupled to the upper surface portion 210 through fasteners, such as bolts B. As a result, the electrostatic chuck 100 can be readily attached and detached (e.g., is removably attached or coupled). Each bolt B may penetrate (or may extend through) the fourth surface 212 and the third surface 211 of the upper surface portion 210 and may be coupled to the connecting portion 220. Bolt holes may be provided at the upper end of the connecting portion 220 for fastening the bolts B.

Each of the actuators 300 may be coupled to the electrostatic chuck 100 and the upper surface portion 210 of the reinforcement frame 200. Each of the actuators 300 may generate a pushing or pulling force in the third direction DR3 on the electrostatic chuck 100 based on the supply of electricity (e.g., according to a supplied electrical power or current). Additionally, the electrical supply to each of the actuators 300 may be individually controlled. For example, the amount of electrical supply to any one of the actuators 300 may differ from the amount of electrical supply to another one of the actuators 300. As a result, the magnitude of the force generated by each of the actuators 300 may vary, and the force transmitted to different regions of the electrostatic chuck 100 may differ accordingly. For example, a relatively higher electrical supply may be provided to the actuators 300 arranged in the central region, where the sagging of the electrostatic chuck 100 is most pronounced. As a result, the sagging of the electrostatic chuck 100 may be improved, and its flatness may be adjusted.

The actuators 300 may constitute a type of flatness control structure. The term “flatness control structure” may refer to every possible type of structure capable of generating a force for pushing or pulling the electrostatic chuck 100 in the third direction DR3 by being coupled to the electrostatic chuck 100 and the upper surface portion 210 of the reinforcement frame 200 to adjust the flatness of the electrostatic chuck 100. As used herein, the flatness control structure may encompass a broader concept than the actuators 300, which are activated by the electrical supply, and may include mechanical devices operated manually.

By allowing the flatness of the electrostatic chuck 100 to be adjusted by the actuators 300, it is possible to perform flatness adjustment in the central region of the electrostatic chuck 100 despite the limited working space. For example, when the flatness of the electrostatic chuck 100 is manually adjusted, the confined space between the reinforcement frame 200 and the ceiling surface of the deposition chamber may render flatness adjustment in the central region of the electrostatic chuck 100 practically impossible. However, embodiments of the present embodiment may mitigate or avoid such an issue.

The actuator 300 may include a piezo actuator having an adjustable length based on the electrical supply. The piezo actuator may provide a pushing force on the electrostatic chuck 100 when its length increases and a pulling force when its length decreases. Piezo actuators can be miniaturized, thereby minimizing or eliminating interference with the arrangement of magnets 420 on the magnet plate 400. However, the actuator 300 is not limited to this configuration and may alternatively include a small motor.

The magnet plate 400 is a device configured to tightly adhere the mask to the substrate by using magnetic force and may be disposed between the electrostatic chuck 100 and the upper surface portion 210 of the reinforcement frame 200 for vertical motion between the electrostatic chuck 100 and the upper surface portion 210 of the reinforcement frame 200. As a result, the tight adherence the mask to the substrate can be improved compared the positioning of the magnet plate 400 on the fourth surface 212 of the upper surface portion 210 of the reinforcement frame 200.

The magnet plate 400 may include a plate portion 410 and magnets 420. The plate portion 410 may have a fifth surface 411 and a sixth surface 412. The fifth surface 411 may face the second surface 102 of the electrostatic chuck 100, and the sixth surface 412 may be an opposite surface to the fifth surface 411. The magnets 420 may be coupled to the fifth surface 411 of the plate portion 410. The magnets 420 may include permanent magnets.

FIG. 4 is a plan view of the electrostatic chuck shown in FIG. 1. For convenience of understanding, the actuators 300 are also illustrated in FIG. 4.

Referring to FIG. 4, the electrostatic chuck 100 may have a peripheral region 102-3 and a central region 102-4 defined therein. The peripheral region 102-3 may refer to a ring-shaped area that is in contact with (e.g., extends from) the first side 102-1 and the second side 102-2 of the second surface 102 of the electrostatic chuck 100. The central region 102-4 may refer to a rectangular area defined by the peripheral region 102-3 within the second surface 102 of the electrostatic chuck 100. The central region 102-4 may not be in contact with (e.g., may be spaced apart from) the first side 102-1 or the second side 102-2. For clarity, the boundary between the peripheral region 102-3 and the central region 102-4 is indicated with dashed lines.

The actuators 300 may include first actuators 310 and second actuators 320. The first actuators 310 may be arranged in a ring shape along the peripheral region 102-3 of the electrostatic chuck 100. The second actuators 320 may be arranged within the central region 102-4 of the electrostatic chuck 100. As a result, sagging issues that may occur as the size of the electrostatic chuck 100 increases can be addressed and corrected.

Owing to the presence of the second actuators 320 in the central region 102-4, the actuators 300 may be arranged in a matrix form with at least three rows and three columns. For example, as illustrated in FIG. 4, the actuators 300 may be arranged in a matrix form having four rows extending in the first direction DR1 and five columns extending in the second direction DR2. However, the arrangement of the actuators 300 is not limited to the illustrated example.

The second actuators 320 may be positioned between a pair of the first actuators 310 along the first direction DR1 and between another pair of the first actuators 310 along the second direction DR2.

FIG. 5 is a bottom view of a portion of the magnet plate 400 shown in FIG. 1. For convenience of understanding, an actuator 300 is also illustrated in FIG. 5. Referring to FIG. 5, the plate portion 410 of the magnet plate 400 may be provided with through-holes (e.g., openings) 413. Each of the through-holes 413 may accommodate an actuator 300. Therefore, interference between the actuator 300 and the magnet plate 400 can be reduced or minimized. The through-holes 413 may be arranged to not overlap with (e.g., to be offset from) the magnets 420 in a plan view. In other words, the through-holes 413 may be provided in regions where the magnets 420 are not positioned in a plan view.

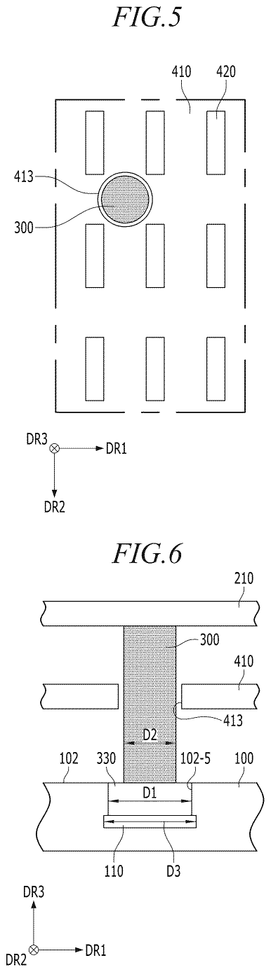

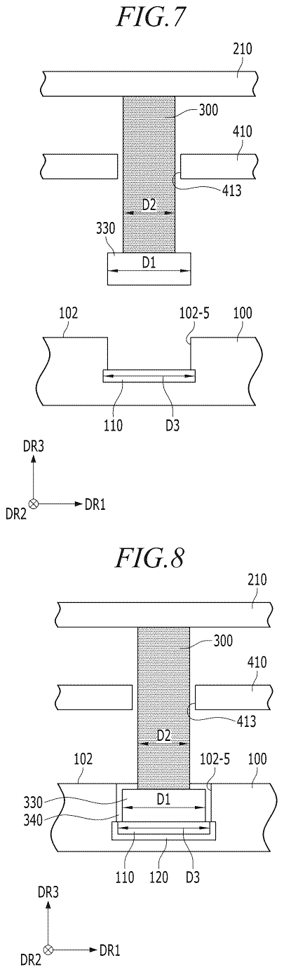

FIG. 6 is a cross-sectional view taken along the line I-I in FIG. 2, and FIG. 7 is a diagram illustrating the permanent electromagnet and the magnetic member in FIG. 6 in a separated state. Referring to FIGS. 6 and 7, the electrostatic chuck assembly 10 may further include permanent electromagnets 330 and magnetic members 110. The permanent electromagnets 330 may be coupled to the ends of the actuators 300. Each of the permanent electromagnets 330 may be switched to a magnetic-on state or a magnetic-off state each time electricity is supplied and may maintain the magnetic-on state or the magnetic-off state even after the electrical supply is interrupted.

For example, when a first electrical supply is applied, the permanent electromagnet 330 may enter the magnetic-on state in which a magnetic force is generated, and the permanent electromagnet 330 may remain in the magnetic-on state even after the electrical supply is interrupted. Moreover, when a second electrical supply is applied, the permanent electromagnet 330 may enter the magnetic-off state in which the magnetic force is nullified, and the permanent electromagnet 330 may maintain the magnetic-off state even after the electrical supply is interrupted. Because the permanent electromagnet 330 is a known device that includes a permanent magnet and an electromagnet, the permanent electromagnet 330 will not be described in greater detail.

The magnetic members 110 may be coupled to the electrostatic chuck 100. The magnetic members 110 may be detachably coupled to the permanent electromagnets 330 by the magnetic force provided by the permanent electromagnets 330. For example, the magnetic members 110 may adhere to the permanent electromagnets 330 when the permanent electromagnets 330 are in the magnetic-on state and may be easily detached from the permanent electromagnets 330 when the permanent electromagnets 330 are in the magnetic-off state. As a result, the actuators 300 may be detachably coupled to the electrostatic chuck 100 via the permanent electromagnets 330 and the magnetic members 110, thereby facilitating attachment and detachment of the electrostatic chuck 100.

The diameter (or maximum width) D1 of the permanent electromagnet 330 may be larger than the diameter (or maximum width) D2 of the actuator 300. This allows the diameter (or maximum width) D2 of the actuator 300 to be reduced or minimized, considering the small pitch of the magnets 420, while ensuring that the permanent electromagnet 330 has a sufficient diameter (or width) D1 to generate the magnetic force to maintain the coupling between the permanent electromagnet 330 and the magnetic member 110.

The second surface 102 of the electrostatic chuck 100 may be provided with receiving holes (e.g., openings) 102-5. The magnetic members 110 may be fixed, respectively, to a bottom surface of the receiving holes 102-5. The permanent electromagnets 330 may be inserted into the receiving holes 102-5 and seated on the magnetic members 110. The receiving holes 102-5 may be configured to guide the movement of the permanent electromagnets 330 in the third direction DR3 when the permanent electromagnets 330 are inserted. Furthermore, the receiving holes 102-5 may reduce or minimize the exposure of surfaces of the permanent electromagnets 330 to the outside, thereby reducing or minimizing the effect of the magnetic force generated by the permanent electromagnets 330 on the magnetic field created by the magnets 420.

The diameter (or maximum width) D3 of the magnetic member 110 may be larger than the diameter (or maximum width) D1 of the permanent electromagnet 330. The magnetic member 110 may cover (or overlap) the permanent electromagnet 330 in a plan view.

Each of the receiving holes 102-5 may include a lower region having a diameter (or maximum width) substantially equal to the diameter (or maximum width) D3 of the magnetic member 110 and an upper region having a diameter (or maximum width) substantially equal to the diameter (or maximum width) D1 of the permanent electromagnet 330.

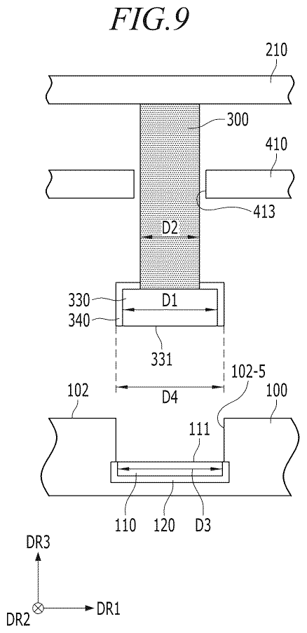

FIGS. 8 and 9 illustrate aspects of an electrostatic chuck assembly according to another embodiment and correspond to FIGS. 6 and 7. Referring to FIGS. 8 and 9, the electrostatic chuck assembly 10 may further include first magnetic shielding caps 340 and second magnetic shielding caps 120.

The first magnetic shielding caps 340 may wrap (or extend) around the permanent electromagnets 330, respectively, and may expose the first attachment surface 331 of each of the permanent electromagnets 330. The first attachment surface 331 of the permanent electromagnets 330 may be the surface facing the magnetic member 110. The first magnetic shielding cap 340 may wrap (or extend) around the top and all side surfaces of the permanent electromagnet 330. The second magnetic shielding caps 120 may wrap (or extend) around the magnetic members 110, respectively, and may expose the second attachment surface 111 of each of the magnetic members 110. The second attachment surface 111 of the magnetic members 110 may be the surface facing the permanent electromagnet 330. The second magnetic shielding cap 120 may wrap (or extend) around the bottom and all side surfaces of the magnetic member 110.

The first attachment surface 331 of the permanent electromagnet 330 may be adhered to the second attachment surface 111 of the magnetic member 110 by the magnetic force provided by the permanent electromagnet 330.

The first magnetic shielding caps 340 and the second magnetic shielding caps 120 may include magnetic shielding material. The magnetic shielding material may refer to a material capable of blocking or significantly reducing propagation of a magnetic force through such a material. As a result, the effect of the magnetic force provided by the permanent electromagnets 330 on the magnetic field created by the magnets 420 may be reduced or eliminated.

The diameter (or maximum width) D4 of the first magnetic shielding cap 340 may be larger than the diameter (or maximum width) D3 of the magnetic member 110. As a result, the magnetic shielding effect can be further improved.

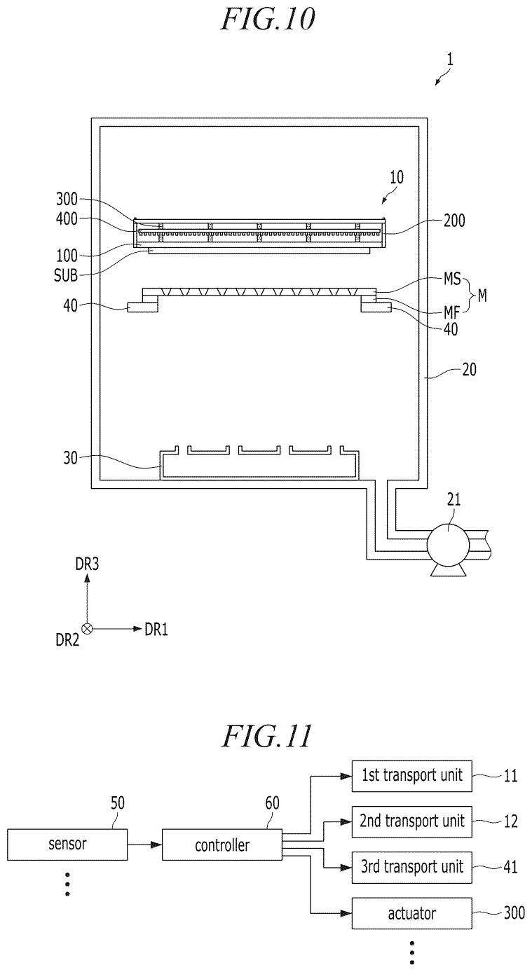

FIG. 10 illustrates a deposition apparatus according to an embodiment of the present disclosure, and FIG. 11 illustrates a controller of the deposition apparatus shown in FIG. 10. Referring to FIGS. 10 and 11, a deposition apparatus 1, according to an embodiment of the present disclosure, may include the electrostatic chuck assembly 10, a first transport unit 11, a second transport unit 12, a vacuum chamber 20, a deposition source 30, a pair of mask holders 40, a third transport unit 41, sensors 50, and a controller 60. However, the deposition apparatus 1 is not limited to including all of the aforementioned components, and in various embodiments, one or more of the components may be omitted.

The electrostatic chuck assembly 10 may be positioned above the deposition source 30 within the vacuum chamber 20. A substrate SUB may be attached to the electrostatic chuck 100 of the electrostatic chuck assembly 10 by an electrostatic force. The substrate SUB may be, but is not limited to, part of a display panel, which will be described later. Before being attached to the electrostatic chuck assembly 10, the substrate SUB may be supported at both ends by substrate holders.

The electrostatic chuck assembly 10 may have the same features as those described with reference to FIGS. 1 to 9 and, thus, will not be described in greater detail.

The first transport unit 11 may be configured to move the electrostatic chuck 100 for transfer and/or alignment of the substrate SUB. The first transport unit 11 may be coupled to the upper surface portion 210 of the reinforcement frame 200. As a result, attachment and detachment of the electrostatic chuck 100 can be facilitated.

The second transport unit 12 may be configured to move the magnet plate 400. For example, when the substrate SUB is attached to the electrostatic chuck 100 and lowered onto the mask M, the second transport unit 12 may lower the magnet plate 400. As a result, the mask M can be tightly adhered to the substrate SUB by the magnetic force provided by the magnet plate 400. The second transport unit 12 may be interlocked operatively and/or structurally with the first transport unit 11.

The vacuum chamber 20 may provide a sealed internal space in which the electrostatic chuck assembly 10, the deposition source 30, and the pair of mask holders 40 are arranged. A vacuum pump 21 may be connected to the vacuum chamber 20. The vacuum pump 21 may be configured to reduce the pressure inside the vacuum chamber 20.

The deposition source 30 may be arranged within the vacuum chamber 20 and may be configured to supply deposition material into the vacuum chamber 20. The deposition source 30 may include a crucible, a heater, and a nozzle. The crucible may be configured to store the deposition material. The heater may be configured to heat the deposition material stored in the crucible. The nozzle may be configured to discharge the vaporized deposition material from the crucible.

The pair of mask holders 40 may support both ends (e.g., opposite ends) of the mask M positioned between the deposition source 30 and the substrate SUB. The pair of mask holders 40 may be, but are not limited to, spaced apart and separable from each other but may also be connected to form an integrated ring. For example, the pair of mask holders 40 may refer to two separate areas of an integrated ring that face each other.

The mask M may include a mask frame MF and a mask sheet MS. The mask frame MF may have a ring shape. The mask sheet MS may include pattern holes (or pattern openings) through which the deposition material can pass. The mask sheet MS may be fixed to the mask frame MF under tension.

The third transport unit 41 may be configured to transport the pair of mask holders 40 for transfer and/or alignment of the mask M. In the illustrated embodiment, the transport unit 11, 12, 41 may include commonly used transport mechanisms in deposition apparatuses, such as UVW stages.

The electrostatic chuck 100 may overlap at least a portion of each of the pair of mask holders 40 in a plan view. For example, instead of using multiple small electrostatic chucks to improve substrate sagging, a single large-area electrostatic chuck 100 may be used.

The sensors 50 may be configured to measure the distance in the third direction DR3 between the electrostatic chuck 100 and the upper surface portion 210 of the reinforcement frame 200 for each of the actuators 300. For example, the sensors 50 may include scales placed adjacent to the actuators 300. In another embodiment, the sensors 50 may be embedded within the actuators 300. For instance, if the actuators 300 are piezo actuators, the piezo actuators may include built-in sensors 50 for measuring the variation of length.

The controller 60 may be configured to individually control the electrical supply to each of the actuators 300 based on the measurements from the sensors 50 to automatically adjust the flatness of the electrostatic chuck 100. Additionally, the controller 60 may be configured to control the first transport unit 11, the second transport unit 12, and the third transport unit 41 according to a pre-set program based on various sensing information.

The controller 60 and/or any other relevant devices or components according to embodiments of the present disclosure described herein may be implemented utilizing any suitable hardware, firmware (e.g., an application-specific integrated circuit), software, and/or a suitable combination of software, firmware, and hardware. For example, the various components of the controller 60 may be formed on one integrated circuit (IC) chip or on separate IC chips. Further, the various components of the controller 60 may be implemented on a flexible printed circuit film, a tape carrier package (TCP), a printed circuit board (PCB), or formed on a same substrate as the controller 60. Further, the various components of the controller 60 may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device or the functionality of a particular computing device may be distributed across one or more other computing devices without departing from the scope of the present disclosure.

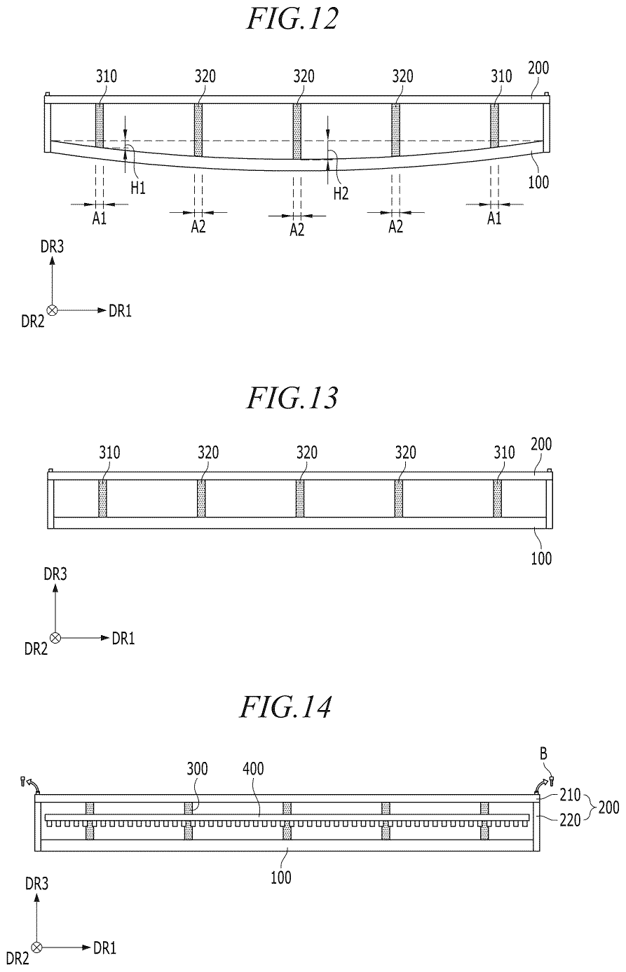

FIGS. 12 and 13 are diagrams comparing the flatness of the electrostatic chuck before and after automatic flatness adjustment in the electrostatic chuck assembly 10 shown in FIG. 10. For simplicity in the illustrations, the magnet plate 400 is omitted in FIGS. 12 and 13.

Referring to FIG. 12, the electrostatic chuck 100 may experience sagging due to its own weight before the flatness adjustment. This sagging may be more pronounced in when the electrostatic chuck 100 is a large-area electrostatic chuck. Additionally, the sagging distance in the second regions A2 of the electrostatic chuck 100 overlapping with the second actuators 320 in a plan view may be greater than the sagging distance in the first regions A1 of the electrostatic chuck 100 overlapping with the first actuators 310 in a plan view. These region-specific sagging distances may be measured by the respective sensors 50, and the controller 60 may individually control the electrical supply to each of the actuators 300 to compensate for the sagging distances.

Referring to FIGS. 12 and 13, the controller 60 may be configured to perform the automatic flatness adjustment of the electrostatic chuck 100 by using the actuators 300. The lift height H2 of the second regions A2 of the electrostatic chuck 100, controlled by the second actuators 320, may be greater than the lift height H1 of the first regions A1 of the electrostatic chuck 100, controlled by the first actuators 310.

FIGS. 14 to 16 are diagrams illustrating a method of attaching and detaching the electrostatic chuck shown in FIG. 10. Referring to FIG. 14, in a step of separating the reinforcement frame, the connecting portion 220 of the reinforcement frame 200 may be separated from the upper surface portion 210 by removing the bolts B. Before this step, the permanent electromagnets may be switched to the magnetic-off state.

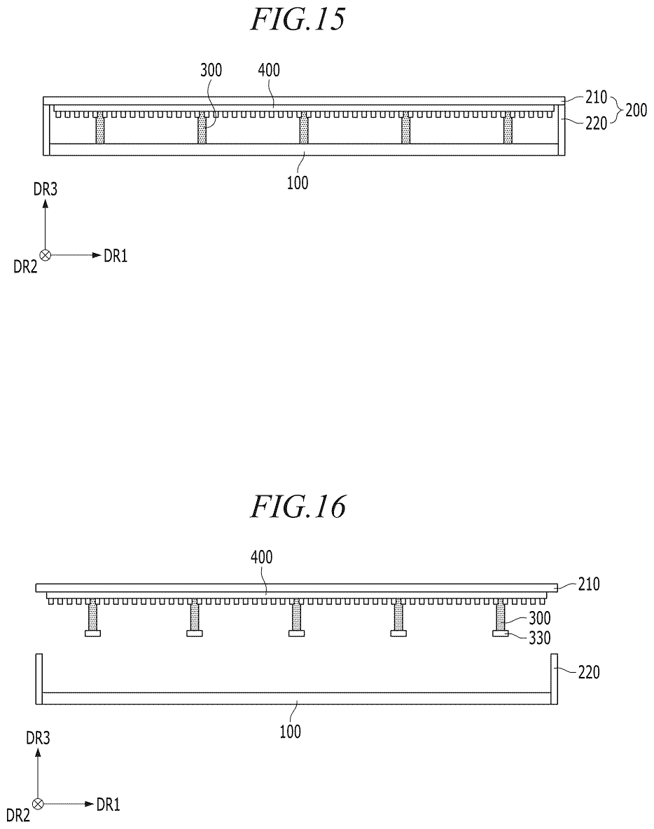

In a step of switching the permanent electromagnets to the magnetic-off state, electrical power may be supplied to the permanent electromagnets 330 to switch each of the permanent electromagnet 330 from the magnetic-on state to the magnetic-off state. However, the method is not necessarily limited to this, and the step of switching the permanent electromagnets to the magnetic-off state may be performed between the step of separating the reinforcement frame and the step of separating the electrostatic chuck shown in FIG. 16.

Referring to FIG. 15, after the step of separating the reinforcement frame, the magnet plate may be lifted. In the step of lifting the magnet plate, the magnet plate 400 may be elevated. As a result, interference with the magnet plate 400 may be reduced or minimized when the electrostatic chuck 100 is separated. However, the method is not necessarily limited to this, and the step of lifting the magnet plate may be omitted or performed before the step of separating the reinforcement frame.

Referring to FIG. 16, in a step of separating the electrostatic chuck, the electrostatic chuck 100 may be separated from the constraint of the upper surface portion 210 of the reinforcement frame 200 and the actuators 300. The attachment of the electrostatic chuck 100 may be performed by reversing the above-described method of separating the electrostatic chuck. Accordingly, the time and labor required for replacement operations, such as when the electrostatic chuck 100 is shorted, is reduced.

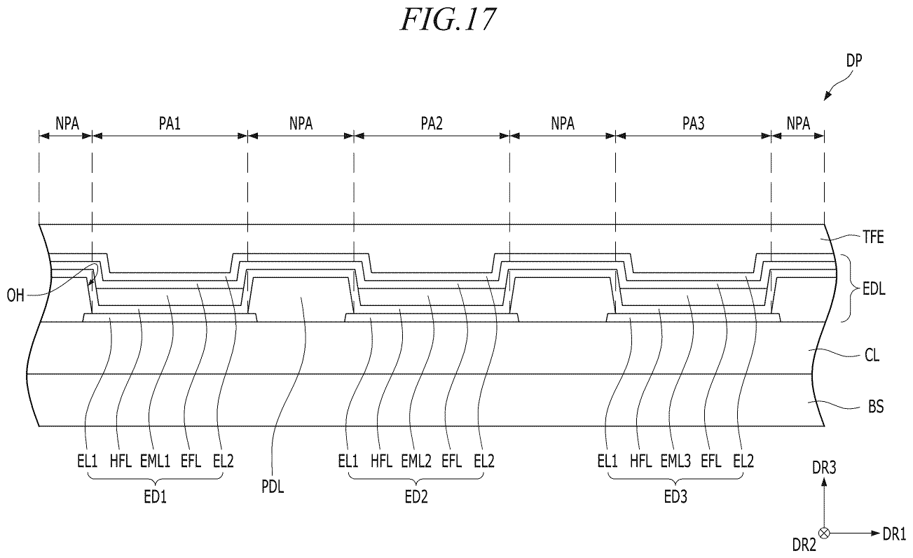

FIG. 17 is a cross-sectional view illustrating a display panel manufactured by using the deposition apparatus according to an embodiment of the present disclosure. Referring to FIG. 17, the display panel DP may include a base substrate BS, a circuit layer CL, a display element layer EDL, and an encapsulation layer TFE.

The base substrate BS may a member providing a base surface on which the circuit layer CL is arranged. The base substrate BS may include materials such as glass, ceramics, metals, or polymer resins, such as polyimide. However, the base substrate BS is not limited to these and may be (or may include) inorganic layers, organic layers, and composite layers and may be formed as a single layer or multiple layers.

The circuit layer CL may be arranged on the base substrate BS and may include pixel circuits and signal wirings. The pixel circuits may include pixel transistors configured to drive light-emitting diodes. Additionally, the circuit layer CL may include peripheral transistors positioned in a non-display area of the display panel DP to output signals for controlling pixel transistors of the pixel circuits.

The display panel DP may have a display area and a non-display area defined therein. The display area is a region where images are displayed, and the non-display area is region a surrounding (e.g., extending around a periphery of) the display area where no images are displayed.

Pixels configured to render images may be arranged in the display area. Each of the pixels may include a light-emitting diode and a pixel circuit. The pixel circuit may be configured to control the operation of the light-emitting diode.

The display element layer EDL may be arranged on the circuit layer CL and may include light-emitting diodes ED1, ED2, ED3, as well as a pixel defining layer PDL. Each of the light-emitting diodes ED1, ED2, ED3 may include a first electrode EL1, a hole functional layer HFL, an emissive layer EML1, EML2, EML3, an electron functional layer EFL, and a second electrode EL2.

The pixel defining layer PDL may be arranged on the circuit layer CL to cover an area between the first electrodes EL1 in a plan view. The pixel defining layer PDL may be arranged to correspond to a non-emissive area NPA. The pixel defining layer PDL may define emissive areas PA1, PA2, PA3 and may separate the light-emitting diodes ED1, ED2, ED3. The pixel defining layer PDL may include one or more organic insulating materials selected from the group consisting of polyimide, polyamide, acrylic resin, benzocyclobutene, and phenolic resin.

The first electrode EL1 may be arranged on the circuit layer CL. The first electrode EL1 may have conductivity and may be electrically connected to the pixel transistor to receive electrical signals.

The hole functional layer HFL may be configured to facilitate the movement of holes from the first electrode EL1 to the emissive layers EML1, EML2, EML3, while the electron functional layer EFL may facilitate the movement of electrons from the second electrode EL2 to the emissive layers EML1, EML2, EML3.

The hole functional layer HFL may be disposed between the first electrode EL1 and the emissive layers EML1, EML2, EML3, and the electron functional layer EFL may be disposed between the second electrode EL2 and the emissive layers EML1, EML2, EML3. However, the arrangement is not necessarily limited to this configuration, and the positions of the hole functional layer HFL and the electron functional layer EFL may be switched depending on the polarity of the first electrode EL1 and the second electrode EL2.

The hole functional layer HFL and the electron functional layer EFL may be provided, but is not limited to, as a common layer, as illustrated. However, either or both of the hole functional layer HFL and the electron functional layer EFL may be patterned to be arranged only within openings OH defined in the pixel defining layer PDL.

The emissive layers EML1, EML2, EML3 may be arranged within the openings OH defined in the pixel defining layer PDL.

At least some of the emissive layers EML1, EML2, EML3 may be configured to emit light in different wavelength ranges. For example, the emissive layer EML1 of the first light-emitting diode ED1 may be configured to emit red light, the emissive layer EML2 of the second light-emitting diode ED2 may be configured to emit green light, and the emissive layer EML3 of the third light-emitting diode ED3 may be configured to emit blue light. However, the present disclosure is not necessarily limited to this configuration, and the emissive layers EML1, EML2, EML3 of the first to third light-emitting diodes ED1, ED2, ED3 may all be configured to emit light in the same wavelength range, such as blue light.

The emissive layers EML1, EML2, EML3 may be formed by using the deposition apparatus 1, according to an embodiment of the present disclosure. However, the present disclosure is not necessarily limited to this configuration, and other layers of the display panel DP that are formed through deposition processes may also be formed using the deposition apparatus 1.

The second electrode EL2 may be arranged on the emissive layers EML1, EML2, EML3. The second electrode EL2 may face the first electrode EL1. The second electrode EL2 may have an integrated shape extending from the emissive areas PA1, PA2, PA3 to the non-emissive areas NPA. The second electrode EL2 may be a common electrode.

The encapsulation layer TFE may be arranged on the display element layer EDL and may be configured to protect the light-emitting diodes ED1, ED2, ED3 of the display element layer EDL from moisture, oxygen, and/or foreign substances. The encapsulation layer TFE may include a glass substrate or a synthetic resin substrate. However, the present disclosure is not necessarily limited to this configuration, and the encapsulation layer TFE may be an inorganic layer, an organic layer, or a stacked structure of inorganic and organic layers.

Hitherto, embodiments of the present disclosure have been described above, but these are merely examples and are not intended to limit the present disclosure. Those skilled in the art to which the present disclosure pertains may make various modifications and changes to the embodiments by adding, changing, deleting, or adding certain elements, without departing from the scope of the technical ideas of the present disclosure as set forth in the claims and their equivalents, and such modifications and changes should also be regarded as being within the scope of the present disclosure.

What is claimed is:

1. An electrostatic chuck assembly comprising:
an electrostatic chuck having a first surface configured to attach a substrate and a second surface opposite to the first surface;
a reinforcement frame having an upper surface portion spaced apart from and facing the second surface of the electrostatic chuck and a connecting portion connecting the upper surface portion with the electrostatic chuck; and
actuators coupled to the electrostatic chuck and the upper surface portion, the actuators being configured to generate a pushing or pulling force on the electrostatic chuck in a third direction, the third direction intersecting a first direction and a second direction parallel to the second surface of the electrostatic chuck, according to an electrical supply.

2. The electrostatic chuck assembly according to claim 1, wherein the connecting portion is coupled to opposite ends of the electrostatic chuck in the first direction or the second direction.

3. The electrostatic chuck assembly according to claim 1, wherein the upper surface portion has a third surface facing the electrostatic chuck and a fourth surface opposite to the third surface, and
wherein the connecting portion is detachably coupled to the upper surface portion by fasteners that are coupled to the connecting portion by extending through the fourth surface and the third surface of the upper surface portion.

4. The electrostatic chuck assembly according to claim 1, wherein the electrical supply to each of the actuators is individually controllable.

5. The electrostatic chuck assembly according to claim 1, wherein each of the actuators comprises a piezo actuator having an adjustable length based on the electrical supply.

6. The electrostatic chuck assembly according to claim 1, wherein the actuators comprise:
first actuators arranged in a ring shape along a peripheral region of the second surface; and
second actuators arranged in a central region of the second surface defined by the peripheral region.

7. The electrostatic chuck assembly according to claim 6, wherein the actuators are arranged in a matrix having at least three rows and three columns.

8. The electrostatic chuck assembly according to claim 6, wherein the second surface has a first side extending in the first direction and a second side extending in the second direction intersecting the first direction, and
wherein each of the second actuators is arranged between a pair of first actuators from among the first actuators in the first direction and between another pair of first actuators from among the first actuators in the second direction.

9. The electrostatic chuck assembly according to claim 1, wherein the actuators are detachably coupled to the electrostatic chuck via permanent electromagnets and magnetic members,
wherein the permanent electromagnets are coupled to respective ends of the actuators, and
wherein the magnetic members are coupled to the electrostatic chuck and are detachably coupled to the permanent electromagnets by magnetic force provided by the permanent electromagnets.

10. The electrostatic chuck assembly according to claim 9, wherein each of the permanent electromagnets is switched to a magnetic-on state or a magnetic-off state each time electricity is supplied and maintains the magnetic-on state or the magnetic-off state after the electrical supply is interrupted.

11. The electrostatic chuck assembly according to claim 9, further comprising:
first magnetic shielding caps that extend around each of the permanent electromagnets while exposing a first attachment surface of each of the permanent electromagnets; and
second magnetic shielding caps that extend around each of the magnetic members while exposing a second attachment surface of each of the magnetic members,
wherein the first attachment surface of each of the permanent electromagnets and the second attachment surface of each of the magnetic members are arranged to face each other and adhere together by magnetic force.

12. The electrostatic chuck assembly according to claim 1, further comprising a magnet plate configured to move vertically between the electrostatic chuck and the upper surface portion, the magnet plate comprising:
a plate portion having a fifth surface facing the electrostatic chuck and a sixth surface opposite to the fifth surface; and
magnets coupled to the fifth surface of the plate portion.

13. The electrostatic chuck assembly according to claim 12, wherein the plate portion has through-holes accommodating the actuators, and
wherein the through-holes are arranged to not overlap with the magnets in a plan view.

14. An electrostatic chuck assembly comprising:
an electrostatic chuck having a first surface to which a substrate is attached and a second surface opposite to the first surface;
a reinforcement frame having an upper surface portion spaced apart from and facing the second surface of the electrostatic chuck and a connecting portion connecting the upper surface portion with the electrostatic chuck; and
flatness control structures coupled to the electrostatic chuck and the upper surface portion and configured to generate a pushing or pulling force on the electrostatic chuck in a third direction perpendicular to the second surface of the electrostatic chuck,
wherein the flatness control structures are detachably coupled to the electrostatic chuck via permanent electromagnets and magnetic members,
wherein the permanent electromagnets are coupled to respective ends of the flatness control structures, and
wherein the magnetic members are coupled to the electrostatic chuck and are detachably coupled to the permanent electromagnets by magnetic force provided by the permanent electromagnets.

15. The electrostatic chuck assembly according to claim 14, wherein the upper surface portion has a third surface facing the electrostatic chuck and a fourth surface opposite to the third surface, and
wherein the connecting portion is detachably coupled to the upper surface portion by fasteners that that are coupled to the connecting portion by extending through the fourth surface and the third surface of the upper surface portion.

16. The electrostatic chuck assembly according to claim 14, further comprising:
first magnetic shielding caps that extend around each of the permanent electromagnets while exposing a first attachment surface of each of the permanent electromagnets; and
second magnetic shielding caps that extend around each of the magnetic members while exposing a second attachment surface of each of the magnetic members,
wherein the first attachment surface of each of the permanent electromagnets and the second attachment surface of each of the magnetic members are arranged to face each other and adhere together by magnetic force.

17. A deposition apparatus comprising:
a vacuum chamber;
a deposition source arranged within the vacuum chamber and configured to supply deposition material into the vacuum chamber;
an electrostatic chuck assembly above the deposition source and having a substrate attached thereto; and
a pair of mask holders configured to support both ends of a mask arranged between the deposition source and the substrate,
wherein the electrostatic chuck assembly comprises:
an electrostatic chuck having a first surface to which the substrate is attached and a second surface opposite to the first surface;
a reinforcement frame having an upper surface portion spaced apart from and facing the second surface of the electrostatic chuck and a connecting portion connecting the upper surface portion with the electrostatic chuck; and
actuators coupled to the electrostatic chuck and the upper surface portion, the actuators being configured to generate a pushing or pulling force on the electrostatic chuck in a third direction, the third direction intersecting a first direction and a second direction parallel to the second surface of the electrostatic chuck, according to an electrical supply.

18. The deposition apparatus according to claim 17, wherein the electrostatic chuck overlaps at least a portion of each of the pair of mask holders in a plan view.

19. The deposition apparatus according to claim 17, further comprising:
sensors configured to measure a distance in the third direction between the electrostatic chuck and the upper surface portion corresponding to each of the actuators; and
a controller configured to automatically adjust flatness of the electrostatic chuck by individually controlling electrical supply to each of the actuators based on the distance measured by the sensors.

20. The deposition apparatus according to claim 19, wherein the actuators comprise:
first actuators arranged in a ring shape along a peripheral region of the second surface; and
second actuators arranged in a central region of the second surface defined by the peripheral region,
wherein an elevation distance of second regions of the electrostatic chuck by the second actuators is greater than an elevation distance of first regions of the electrostatic chuck by the first actuators.
